(19) United States
(12) Patent Application Publication
(10) Pub. No.: US 2015/0092149 A1
(43) Pub. Date: Apr. 2, 2015

(54) LIQUID CRYSTAL DISPLAY AND METHOD FOR MANUFACTURING THE SAME

(71) Applicant: Samsung Display Co., Ltd., Yongin-City (KR)

(72) Inventors: Daisuke INOUE, Cheonan-si (KR); Mi Suk KIM, Cheonan-si (KR); Tae Ho KIM, Asan-si (KR); Si Heun KIM, Asan-si (KR); So Youn PARK, Hwaseong-si (KR); Keun Chan OH, Cheonan-si (KR); Chang-Hun LEE, Hwaseong-si (KR)

(21) Appl. No.: 14/338,971

(22) Filed: Jul. 23, 2014

(30) Foreign Application Priority Data
Oct. 2, 2013 (KR) 10-2013-0117934

(51) Int. Cl. G02F 1/1343; H01L 27/12; G02F 1/1362

(52) U.S. Cl. CPC G02F 1/134363; G02F 1/136286; H01L 27/1259; G02F 2001/134318
USPC 349/138; 438/30

(57) ABSTRACT

A liquid crystal display includes: a substrate; and a common electrode disposed on the substrate; a pixel electrode disposed on the substrate; and an insulating layer disposed between the common electrode and the pixel electrode, in which at least one of the common electrode and the pixel electrode includes a plurality of slit electrodes defined by a plurality of cutouts defined therein, and a width of a slit electrode of the slit electrodes, a distance between the slit electrodes, and a thickness of the insulating layer satisfy the following in equation: 0.01x−0.2y+0.31≦L/P≦0.01x−0.2y+0.41, L denotes the width of the slit electrode, P denotes the distance between the slit electrodes, x denotes a value of the distance between the slit electrodes in micrometers, and y denotes a value of the thickness of the insulating layer in micrometers.

This application claims priority to Korean Patent Application No. 10-2013-0117934 filed on Oct. 2, 2013, and all the benefits accruing therefrom under 35 U.S.C. §119, the contents of which are incorporated by reference herein in its entirety.

### BACKGROUND

(a) Field

Exemplary embodiments of the invention relate to a liquid crystal display and a method of manufacturing the liquid crystal display.

(b) Description of the Related Art

In general, a liquid crystal panel uses a twisted nematic (“TN”) mode, and recently, has widely used a plane-to-line switching (“PLS”) mode for ensuring a wide viewing angle.

The PLS mode liquid crystal panel includes a pixel electrode and a common electrode that overlaps the pixel electrode on a substrate with a thin film transistor to implement grayscale display while horizontally-aligned liquid crystal molecules rotate by an electric field applied between the pixel electrode and the common electrode.

However, in a wedge type electrode structure, a phenomenon where polarization is generated by splay deformation, bending deformation or the like is generally known as a flexoelectric effect. Generally, the flexoelectric effect is known to occur in the case where a liquid crystal injected to a wedge type cell or a cell is deformed, but macroscopic polarization due to the flexoelectric effect may be generated even in the case where alignment deformation such as the splay deformation, the bending deformation or the like, occurs, when a fringe field is applied to the liquid crystal molecules and the liquid crystal molecules are aligned in an electric field direction as in the PLS.

### SUMMARY

Further, in the liquid crystal display, to effectively prevent degradation of a liquid crystal material, alternating current (“AC”) driving is generally performed, and a polarity of a potential difference between voltages of the pixel electrode and the common electrode is periodically inverted. In the case where the liquid crystal having the flexoelectric effect is used in such a liquid crystal display, even though the polarity of the potential difference is inverted in the AC driving, the polarity of the polarization of the liquid crystal may not be effectively inverted due to the flexoelectric effect. As a result, light transmittance varies for each pixel according to the polarity of the potential difference. Particularly, in the case where the AC driving is performed in the liquid crystal to invert the polarity of the potential difference in each frame, light transmittance between a positive (+) frame where a voltage of the pixel electrode is larger than a voltage of the common electrode and a negative (−) frame where the voltage of the pixel electrode is smaller than the voltage of the common electrode varies. Accordingly, a flicker and an afterimage may occur due to non-uniform luminance of the liquid crystal display between frames.

Accordingly, exemplary embodiments of the invention has been made in an effort to provide a liquid crystal display with improved display characteristic and a method of manufacturing the liquid crystal display in which problems such as a flicker and an afterimage is effectively prevented by controlling a relationship among a width of a slit electrode part, a distance between the slit electrode parts, and a thickness of an insulating layer.

An exemplary embodiment of the invention provides a liquid crystal display including: a substrate; and a common electrode disposed on the substrate; a pixel electrode disposed on the substrate; and an insulating layer disposed between the common electrode and the pixel electrode, in which at least one of the common electrode and the pixel electrode includes a slit electrode (e.g., a plurality of silt electrodes) defined by a plurality of cutouts defined therein, and a width of the slit electrode, a distance between the slit electrodes, and a thickness of the insulating layer satisfy the following in equation: 0.01x−0.2y+0.31≦L/P≦0.01x−0.2y+0.41, L denotes the width of the slit electrode, P denotes the distance between the slit electrodes, x denotes a value of the distance between the slit electrodes in micrometers, and y denotes a value of the thickness of the insulating layer in micrometers.

In an exemplary embodiment, the width of the slit electrode, the distance between the slit electrodes, and the thickness of the insulating layer may satisfy the following equation: L/P=0.01x−0.2y+0.36.

In an exemplary embodiment, the liquid crystal display may further include a gate line disposed on the substrate; a first passivation layer disposed on the gate line and the substrate; a semiconductor layer disposed on the insulating layer; a data line and a drain electrode disposed on the semiconductor layer; a second passivation layer disposed on the data line and the drain electrode, where the common electrode and the pixel electrode are disposed on the second passivation layer.

In an exemplary embodiment, the pixel electrode and the common electrode may include a transparent conductive layer.

In an exemplary embodiment, the data line may include a first curved portion having a curved shape, and a second curved portion curved to form a predetermined angle with the first curved portion.

In an exemplary embodiment, the liquid crystal display may further include a source electrode disposed on the semiconductor layer, where the source electrode and the data line may be disposed along a same line.

In an exemplary embodiment, the drain electrode and the data line may extend substantially parallel to each other.

In an exemplary embodiment, the common electrode may include a curved edge substantially parallel to the first curved portion and the second curved portion of the data line.

Another exemplary embodiment of the invention provides a manufacturing method of a liquid crystal display, the manufacturing method including: providing a common electrode and a pixel electrode on a substrate; providing an insulating layer between the common electrode and the pixel electrode; and providing a plurality of slit electrodes by forming a plurality of cutouts in at least one of the common electrode and pixel electrode, in which a width of a slit electrode of the slit electrodes, a distance between the slit electrodes and a thickness of the insulating layer satisfy the following in equation: 0.01x−0.2y+0.31≦L/P≦0.01x−0.2y+0.41, wherein L denotes the width of the slit electrode, P denotes the distance between the slit electrodes, x denotes a value of a distance between the slit electrodes in micrometers, and y denotes a value of the thickness of the insulating layer in micrometers.

In an exemplary embodiment, the width of the slit electrode, the distance between the slit electrodes, and the thickness of the insulating layer may satisfy the following equation: L/P=0.01x−0.2y+0.36.

In an exemplary embodiment, the manufacturing method of a liquid crystal display may further include providing a gate line on the substrate; providing a first passivation layer on the gate line and the substrate; providing a semiconductor layer on the insulating layer; providing a data line and a drain electrode on the semiconductor layer; providing a second passivation layer on the data line and the drain electrode and below the common electrode and the pixel electrode.

As described above, in exemplary embodiments of the liquid crystal display, according to the invention, a difference in luminance between a positive frame and a negative frame and a flicker are reduced by controlling a width of a slit electrode portion, a distance between the slit electrode portions and a thickness of an insulating layer to satisfy a predetermined condition, thereby substantially improving display quality of the liquid crystal display.

### BRIEF DESCRIPTION OF THE DRAWINGS

The above and other features of the invention will become more apparent by describing in detail exemplary embodiments thereof with reference to the accompanying drawings, in which:

FIG. 1 is a top plan view of an exemplary embodiment of a liquid crystal display, according to the invention;

FIG. 2 is a cross-sectional view taken along line II-II of the liquid crystal display of FIG. 1;

FIG. 3 is a top plan view of an alternative exemplary embodiment of a liquid crystal display, according to the invention;

FIG. 4 is a cross-sectional view taken along line IV-IV of the liquid crystal display of FIG. 3;

FIG. 5 is a graph illustrating a luminance profile of a positive frame and a negative frame in a pixel area of a liquid crystal display;

FIG. 6A is a graph illustrating voltage to transmittance when a width of a slit electrode portion is about 2.79 micrometers (μ), a distance between the slit electrode portions is about 8 μm, a cell gap is about 3.0 μm, and a thickness of an insulating layer is about 3,000 angstroms (A) in an exemplary embodiment of the liquid crystal display;

FIG. 6B is an enlarged view of the portion A in FIG. 6A;

FIG. 6C is an enlarged view of the portion B in FIG. 6A;

FIG. 7A is a graph illustrating voltage to transmittance when a width of a slit electrode portion is about 3.50 μm, a distance between the slit electrode portions is about 8 μm, a cell gap is about 3.0 μm, and a thickness of an insulating layer is about 3,000 Å in an exemplary embodiment of the liquid crystal display;

FIG. 7B is an enlarged view of the portion A′ in FIG. 7A;

FIG. 7C is an enlarged view of the portion B′ in FIG. 7A;

FIG. 8 is a graph measuring a difference in transmittance according to voltages of the positive frame and the negative frame while the width of the slit electrode portion is changed under the same condition as FIG. 6A;

FIG. 9 is a graph measuring luminance according to a width of the slit electrode portion/a distance between the slit electrode portions in an exemplary embodiment of the liquid crystal display, when a thickness of the insulating layer is about 200 nanometers (nm);

FIG. 10 is a graph measuring luminance according to a width of the slit electrode portion/a distance between the slit electrode portions in an exemplary embodiment of the liquid crystal display, when a thickness of the insulating layer is 400 nm.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of a liquid crystal display, according to the invention, will be described with reference to the accompanying drawings.

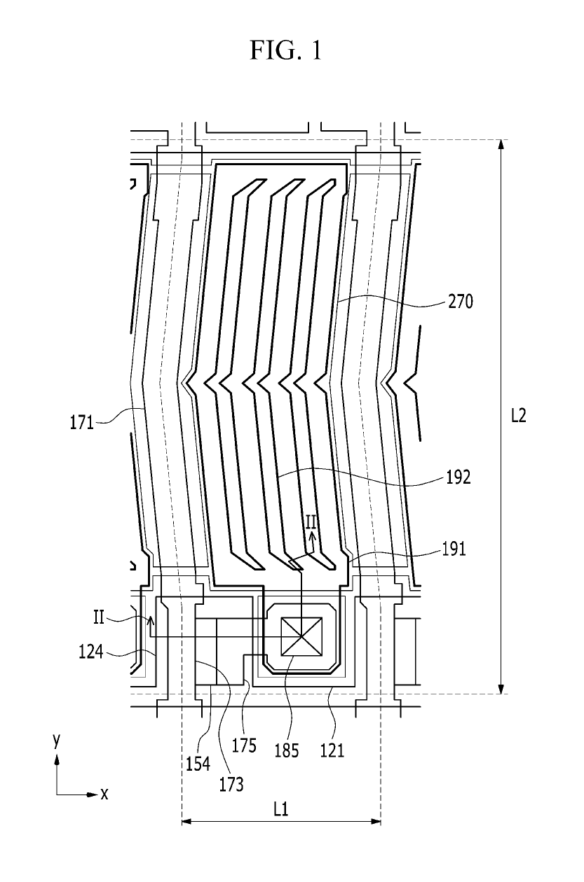

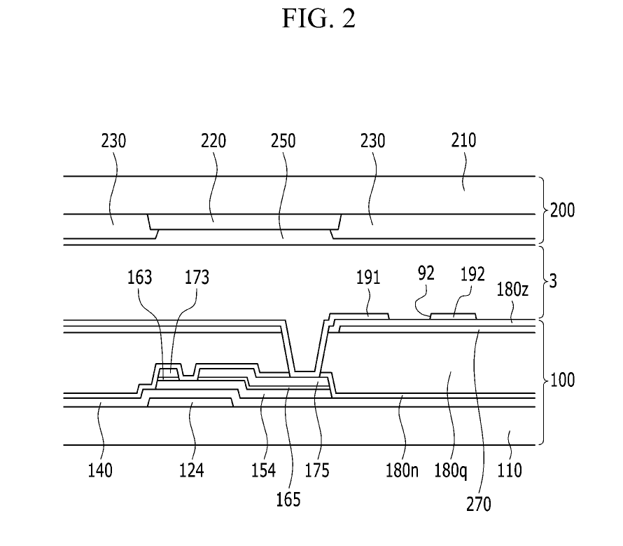

First, an exemplary embodiment of a liquid crystal display, according to the invention, will be described with reference to FIGS. 1 and 2. FIG. 1 is a top plan view of an exemplary embodiment of a liquid crystal display, according to the invention, and FIG. 2 is a cross-sectional view taken along line II-II of the liquid crystal display of FIG. 1.

First, referring to FIGS. 1 and 2, an exemplary embodiment of a liquid crystal display includes a lower panel 100 and an upper panel 200, which are disposed opposite to each other, and a liquid crystal layer 3 interposed therebetween. In an exemplary embodiment, the liquid crystal display may have resolution of about 200 pixels per inch (PPI) or more, that is, pixels of about 200 or more may be included in a region of about 1 inch in width and length of the liquid crystal display. In FIGS. 1 and 2, one pixel area is shown for convenience of illustration and description. In such an embodiment, a horizontal length L1 of one pixel of the liquid crystal display may be about 40 micrometers (μ) or less, and a vertical length L2 of the one pixel area may be about 120 micrometers (μ) or less. Here, as illustrated in the drawings, the horizontal length L1 of a pixel area may be defined as a distance between vertical centers of two adjacent data lines 171 thereof, and the vertical length L2 of the pixel area may be defined as a distance between horizontal centers of two adjacent gate lines 121 thereof.

First, the lower panel 100 will be described.

In the lower panel 100, a gate conductor including a gate line 121 is disposed on an insulation substrate 110 including transparent glass, plastic, or the like, for example.

The gate line 121 includes a gate electrode 124 and a wide end portion (not illustrated) for connection with another layer or an external driving circuit. The gate line 121 may include or be made of aluminum-based metal such as aluminum (Al) or an aluminum alloy, silver-based metal such as silver (Ag) or a silver alloy, copper-based metal such as copper (Cu) or a copper alloy, molybdenum-based metal such as molybdenum (Mo) or a molybdenum alloy, chromium (Cr), tantalum (Ta), titanium (Ti) or a combination thereof. In an exemplary embodiment, the gate line 121 may have a multilayered structure including at least two conductive layers having different physical properties.

A gate insulating layer 140 including silicon nitride (SiNx) or silicon oxide (SiOx) is disposed on a gate conductor 121. The gate insulating layer 140 may have a multilayer structure including at least two insulating layers having different physical properties.

A semiconductor 154 including amorphous silicon or polysilicon is disposed on the gate insulating layer 140. In an exemplary embodiment, the semiconductor 154 may include an oxide semiconductor.

Ohmic contacts 163 and 165 are disposed on the semiconductor 154. The ohmic contacts 163 and 165 may include or be made of a material such as n+ hydrogenated amorphous silicon, in which n-type impurity such as phosphorus is doped at high concentration, or silicide. In an exemplary embodiment, two ohmic contacts 163 and 165 may be disposed on the semiconductor 154 as a pair. In an exemplary embodiment, where the semiconductor 154 is an oxide semiconductor, the ohmic contacts 163 and 165 may be omitted.

A data conductor including a data line 171 including a source electrode 173 and a drain electrode 175 is disposed on the ohmic contacts 163 and 165, and the gate insulating layer 140.

The data line 171 includes a wide end portion (not illustrated) for connection with another layer or an external driving circuit. The data line 171 transfers a data signal and extends substantially in a vertical direction to cross the gate line 121.

In an exemplary embodiment, the data line 171 may have a first curved portion having a curved shape to provide maximum transmittance of the liquid crystal display, and the curved portion may have a V-lettered shape which meets in a middle region of the pixel area. A second curved portion, which is curved to form a predetermined angle with the first curved portion, may be further included in the middle region of the pixel area.

The first curved portion of the data line 171 may be curved to form an angle of about 7° with a vertical reference line (e.g., an imaginary line extending in a Y direction) which forms an angle of 90° with an extending direction (e.g., an X direction) of the gate line 121. The second curved portion disposed in the middle region of the pixel area may be further curved to form an angle of about 7° to about 15° with the first curved portion.

The source electrode 173 is defined by a portion of the data line 171, and disposed on the same line as the data line 171. The drain electrode 175 extends substantially parallel to the source electrode 173. Accordingly, the drain electrode 175 is substantially parallel to a portion of the data line 171.

The gate electrode 124, the source electrode 173 and the drain electrode 175 collectively defines a thin film transistor together with the semiconductor 154, and a channel of the thin film transistor is formed in the semiconductor 154 between the source electrode 173 and the drain electrode 175.

An exemplary embodiment of the liquid crystal display, according to the invention, includes the source electrode 173 disposed in substantially the same line with the data line 171 and the drain electrode 175 extending substantially parallel to the data line 171, such that a width of the thin film transistor may be increased while an area occupied by the data conductor is effectively prevented from being increased, thereby increasing an aperture ratio of the liquid crystal display.

The data line 171 and the drain electrode 175 may include or be made of refractory metal such as molybdenum, chromium, tantalum, and titanium or an alloy thereof, and may have a multilayered structure including a refractory metal layer (not illustrated) and a low resistive conductive layer (not illustrated). In one exemplary embodiment, for example, the multilayered structure may be a double layer including a chromium or molybdenum (alloy) lower layer and an aluminum (alloy) upper layer, or a triple layer including a molybdenum (alloy) lower layer, an aluminum (alloy) intermediate layer, and a molybdenum (alloy) upper layer. However, the data line 171 and the drain electrode 175 may be include or made of various metals or conductors other than the metals listed above. A width of the data line 171 may be about 3.5 μm±0.75 μm, that is, may be in a range from about 2.75 μm to about 4.25 μm.

A first passivation layer 180n is disposed on the data conductor 171, 173 and 175, the gate insulating layer 140 and an exposed portion of the semiconductor 154. The first passivation layer 180n may include or be made of an organic insulating material or an inorganic insulating material.

A second passivation layer 180q is disposed on the first passivation layer 180n. In an alternative exemplary embodiment, the second passivation layer 180q may be omitted. In an exemplary embodiment, the second passivation layer 180q may be a color filter. In such an embodiment, where the second passivation layer 180q is the color filter, the second passivation layer 180b may display one of the primary colors, e.g., three primary colors such as red, green and blue, or yellow, cyan and magenta, and the like. Although not illustrated, the color filters may further include a color filter for displaying a mixed color of the primary colors or white in addition to the primary colors.

A common electrode 270 is disposed on the second passivation layer 180q. The common electrode 270 may include a transparent conductive layer.

The common electrode 270 having a planar shape may be disposed on about the entire surface of the insulation substrate 110 of the lower panel 100, and an opening (not illustrated) may be defined in the common electrode 270 in a region corresponding to a periphery of the drain electrode 175. In such an embodiment, the common electrode 270 may have a plate-like plane shape.

Common electrodes 270 disposed at the adjacent pixels are connected to each other to receive a common voltage having a predetermined magnitude supplied from the outside of a display area.

An insulating layer 180z is disposed on the common electrode 270. The insulating layer 180z may include or be made of an organic insulating material, an inorganic insulating material, or the like.

A pixel electrode 191 is disposed on the insulation layer 180z. The pixel electrode 191 includes a curved edge, which is substantially parallel to a first curved portion and a second curved portion of the data line 171. In an exemplary embodiment, a plurality of cutouts 92 is defined in the pixel electrode 191, and the pixel electrode 191 thereby includes a plurality of first slit electrodes 192 defined by the plurality of cutouts 92. The pixel electrode 191 may include a transparent conductive layer.

A first contact hole 185 that exposes the drain electrode 175 is defined, e.g., formed, through the first passivation layer 180n, the second passivation layer 180q and the insulating layer 180z. The pixel electrode 191 is physically and electrically connected to the drain electrode 175 through the first contact hole 185 to receive a voltage from the drain electrode 175.

In an exemplary embodiment, an alignment layer (not shown) may be disposed or coated on the pixel electrode 191 and the insulating layer 180z, and the alignment layer may be a horizontal alignment layer and be rubbed in a predetermined direction. In an alternative exemplary embodiment of a liquid crystal display, the alignment layer includes a photoreactive material to be photo-aligned.

Next, the upper panel 200 will be described.

In the upper panel 200, a light blocking member 220 is disposed on an insulation substrate 210 including transparent glass, plastic, or the like. The light blocking member 220 is also referred to as a black matrix and blocks light leakage.

A plurality of color filters 230 is disposed on the insulation substrate 210 of the upper panel. In an exemplary embodiment where the second passivation layer 180q of the lower panel 100 is a color filter, the color filter 230 of the upper panel 200 may be omitted. In such an embodiment, the light blocking member 220 of the upper panel 200 may also be disposed on the lower panel 100.

An overcoat 250 is disposed on the color filter 230 and the light blocking member 220. The overcoat 250 may include or be made of an (organic) insulator, thereby effectively preventing the color filter 230 from being exposed, and providing a flat surface. In an alternative exemplary embodiment, the overcoat 250 may be omitted.

An alignment layer may be disposed on the overcoat 250.

The liquid crystal layer 3 includes a nematic liquid crystal material having positive dielectric anisotropy. Liquid crystal molecules of the liquid crystal layer 3 are aligned in a predetermined direction such that longitudinal axes of the liquid crystal molecules are aligned substantially parallel to the lower or upper panels 100 and 200, and the direction has a 90°-twisted structure in a spiral form from a rubbing direction of the alignment layer from the lower panel 100 to the upper panel 200.

The pixel electrode 191 receives a data voltage from the drain electrode 175, and the common electrode 270 receives a common voltage having a predetermined magnitude from a common voltage applying unit disposed outside of the display area.

The pixel electrode 191 and the common electrode 270, which are field generating electrodes, generate an electric field and thus the liquid crystal molecules of the liquid crystal layer 3 positioned on the pixel and common electrodes 191 and 270 rotate in a direction substantially parallel to the direction of the electric field. Polarization of light passing through the liquid crystal layer varies according to the determined rotation directions of the liquid crystal molecules.

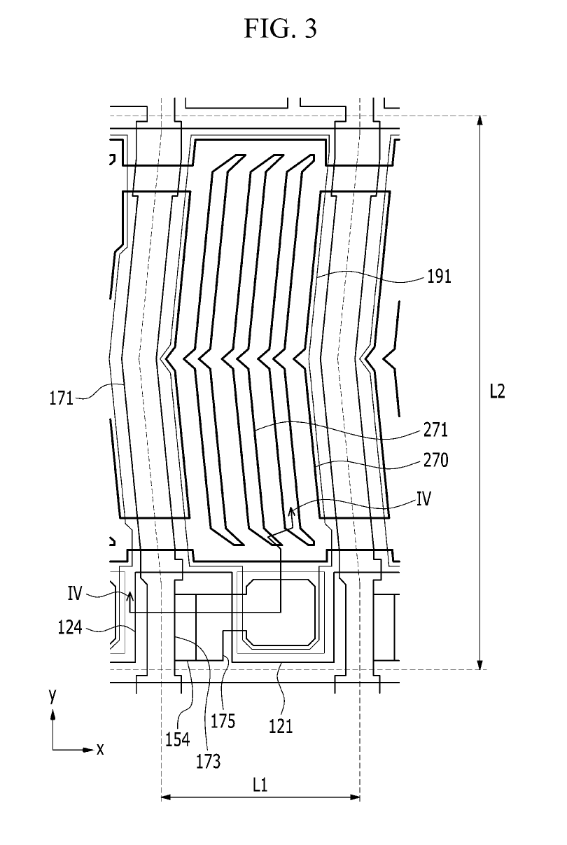

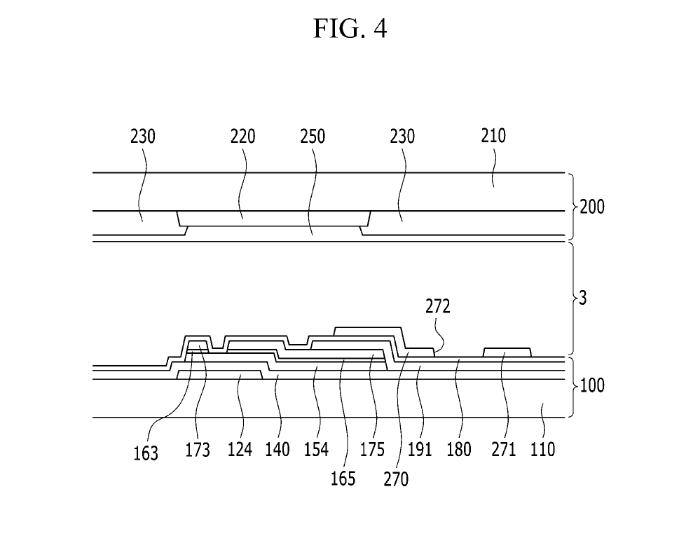

Next, an alternative exemplary embodiment of a liquid crystal display, according to the invention, will be described with reference to FIGS. 3 and 4. FIG. 3 is a plan view of an alternative exemplary embodiment of a liquid crystal display, according to the invention, and FIG. 4 is a cross-sectional view taken along line IV-IV of the liquid crystal display of FIG. 3.

The liquid crystal display shown in FIGS. 3 and 4 is substantially similar to the liquid crystal display illustrated in FIGS. 1 and 2. The same or like elements shown in FIGS. 3 and 4 have been labeled with the same reference characters as used above to describe the exemplary embodiments of the liquid crystal display shown in FIGS. 1 and 2, and any repetitive detailed description thereof will hereinafter be omitted or simplified.

Referring to FIGS. 3 and 4, an exemplary embodiment of a liquid crystal display, according to the invention, includes a lower panel 100 and an upper panel 200, which are disposed opposite to each other, and a liquid crystal layer 3 interposed between the lower and upper panels 100 and 200. In such an embodiment, the liquid crystal display may have resolution of about 200 PPI or more, that is, pixels of about 200 or more may be included in a region of about 1 inch in width and length of the liquid crystal display. In FIGS. 3 and 4, one pixel area is shown for convenience of illustration and description. In such an embodiment, a horizontal length L1 of one pixel area of the liquid crystal display may be about 40 μm or less, and a vertical length L2 of the one pixel area may be about 120 μm or less. Here, as illustrated in the drawings, the horizontal length L1 of a pixel area may be defined as a distance between vertical centers of two adjacent data lines 171, and the vertical length L2 of the pixel area may be defined as a distance between horizontal centers of two adjacent gate lines 121.

First, the lower panel 100 will be described.

In the lower panel 100, a gate conductor including a gate line 121 is disposed on an insulation substrate 110.

A gate insulating layer 140 including silicon nitride (SiNx), silicon oxide (SiOx) or the like, for example, is disposed on a gate conductor 121.

A semiconductor layer 154 is disposed on the gate insulating layer 140.

Ohmic contacts 163 and 165 are disposed on the semiconductor 154. In an exemplary embodiment, where the semiconductor 154 is an oxide semiconductor, the ohmic contacts 163 and 165 may be omitted.

A data conductor including a data line 171 that includes a source electrode 173 and a drain electrode 175 is disposed on the ohmic contacts 163 and 165 and the gate insulating layer 140.

A pixel electrode 191 may be disposed directly on the drain electrode 175. The pixel electrode 191 has a planar shape, that is, a plate shape, and is disposed in each pixel area.

An insulating layer 180 is disposed on the data conductor 171, 173 and 175, the gate insulating layer 140, an exposed portion of the semiconductor 154, and the pixel electrode 191. In an alternative exemplary embodiment of a liquid crystal display according to the invention, the insulating layer 180 is disposed between the pixel electrode 191 and the data line 171, and the pixel electrode 191 may be connected to the drain electrode 175 through a contact hole (not illustrated) defined in the insulating layer 180.

A common electrode 270 is disposed on the passivation layer 180. The common electrodes 270 are connected to each other to receive a common voltage from a reference voltage applying unit disposed outside the display area.

The common electrode 270 includes a curved edge substantially parallel to a first curved portion and a second curved portion, and the common electrodes 270 disposed in the adjacent pixels are connected to each other. In such an embodiment, a plurality of cutouts 272 is defined in the common electrode 270, and the common electrode 270 includes a plurality of second slit electrodes 271 defined by the plurality of cutouts 272.

In an exemplary embodiment, an alignment layer (not shown) is coated on the common electrode 270 and the insulating layer 180, and the alignment layer may be a horizontal alignment layer and be rubbed in a predetermined direction. In an alternative exemplary embodiment of a liquid crystal display, the alignment layer includes a photoreactive material to be photo-aligned.

Next, the upper panel 200 will be described.

In the upper panel 200, a light blocking member 220 is disposed on an insulation substrate 210. In an exemplary embodiment, a plurality of color filters 230 is disposed on the insulation substrate 210 of the upper panel 200. In an alternative exemplary embodiment, the color filters 230 may be disposed on the lower panel 100, and in such an embodiment, the light blocking member 220 may also be disposed on the lower panel 100.

An overcoat 250 is disposed on the color filter 230 and the light blocking member 220. In an alternative exemplary embodiment, the overcoat 250 may be omitted.

An alignment layer may be disposed on the overcoat 250. The liquid crystal layer 3 includes a nematic liquid crystal material having positive dielectric anisotropy. Liquid crystal molecules of the liquid crystal layer 3 are aligned in a predetermined direction such that longitudinal axes of the liquid crystal molecules are aligned substantially parallel to the lower and upper panels 100 and 200, and the direction has a 90°-twisted structure in a spiral form from a rubbing direction of the alignment layer from the lower panel 100 to the upper panel 200.

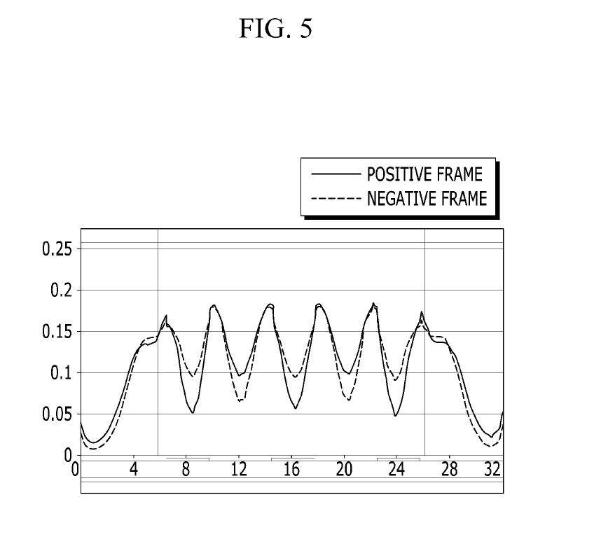

A luminance profile of a positive frame and a negative frame in an exemplary embodiment of the liquid crystal display, according to the invention, will be described with reference to FIG. 5.

FIG. 5 is a graph illustrating a luminance profile of a positive frame and a negative frame in a pixel area of a liquid crystal display.

In FIG. 5, the horizontal axis represents position in the pixel area, and the vertical axis represents luminance. Referring to FIG. 5, during alternating current (“AC”) driving in a plane-to-line switching (“PLS”) mode, when the AC is applied to an electrode (e.g., electrodes disposed at 8, 16 and 24 positions in FIG. 5) as a positive frame and a slit between the electrodes as a negative frame, a texture occurs. In such a liquid crystal display, when the number of slit electrode portions positioned in the curved portion of the pixel electrode or the common electrode is not the same as the number of slits between the slit electrode portions, a difference in luminance between the positive frame and the negative frame is generated, and thus a flicker may occur.

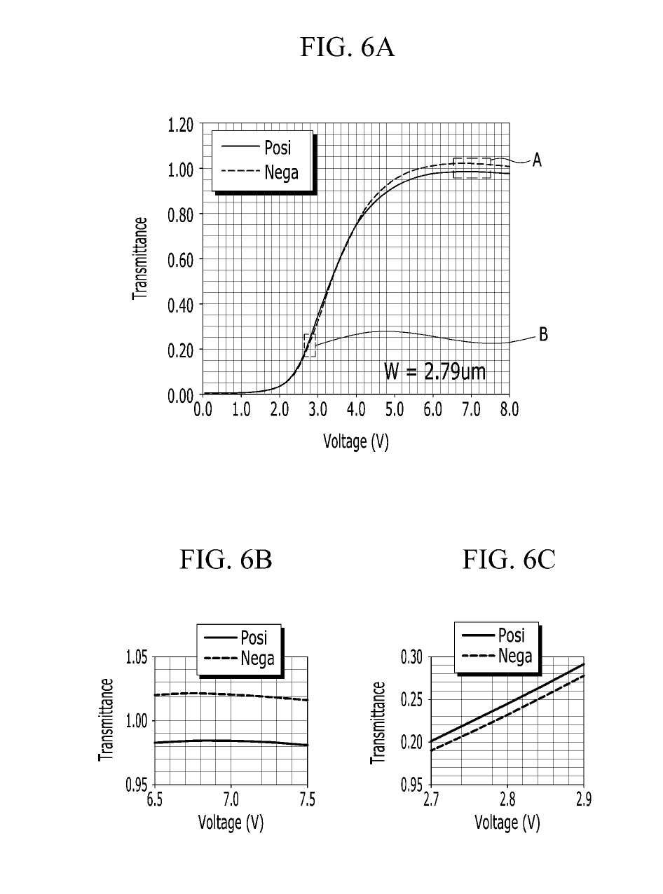

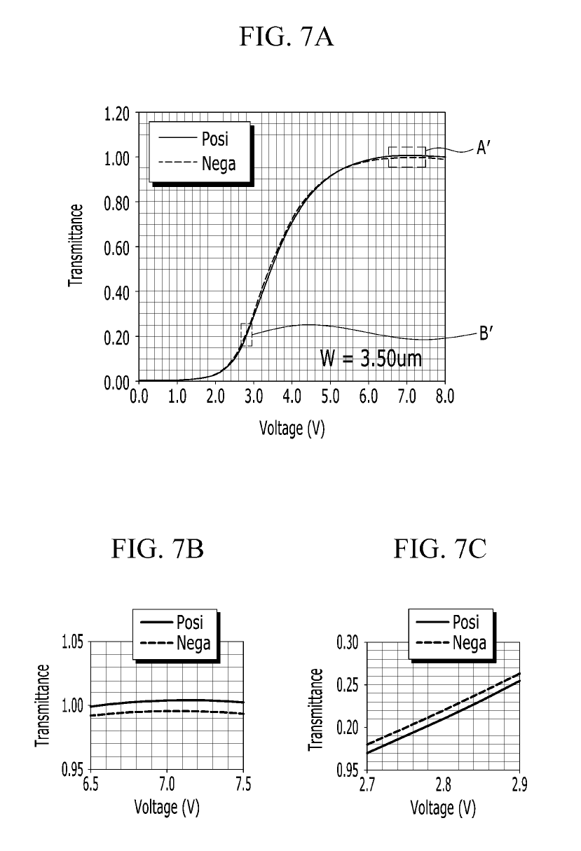

Referring to FIGS. 6A to 7C, voltage to transmittance according to a width of the slit electrode portion/a distance between the slit electrode portions in a negative liquid crystal of an exemplary embodiment of the liquid crystal display, according to the invention, will be described.

FIG. 6A is a graph illustrating voltage to transmittance when a width of a slit electrode portion is about 2.79 μm, a distance between the slit electrode portions is about 8 μm, a cell gap is about 3.0 μm, and a thickness of an insulating layer is about 3,000 Å in an exemplary embodiment of the liquid crystal display, FIG. 6B is an enlarged view of the portion A in FIG. 6A, and FIG. 6C is an enlarged view of the portion B in FIG. 6A. FIG. 7A is a graph illustrating voltage to transmittance when a width of a slit electrode portion is about 3.50 μm, a distance between the slit electrode portions is about 8 μm, a cell gap is about 3.0 μm, and a thickness of an insulating layer is about 3,000 Å in an exemplary embodiment of the liquid crystal display, FIG. 7B is an enlarged view of the portion A′ in FIG. 7A, and FIG. 7C is an enlarged view of the portion B′ in FIG. 7A.

In FIGS. 6A to 7C, horizontal axes represent voltages, and vertical axes represent transmittance.

As shown in graphs of voltage to transmittance in FIGS. 6A to 7C, a difference in transmittance according to a voltage between polarities of the positive frame and the negative frame due to a flexoelectric effect is generated. Accordingly, in an exemplary embodiment of the invention, the difference in transmittance according to a voltage may be reduced by controlling the graphs of the positive frame (Posi) and the negative frame (Nega) to coincide with each other by controlling the distance between the slit electrode portions (e.g., a distance between adjacent silt electrode portions), the thickness of the insulating layer and the width of the slit electrode portion.

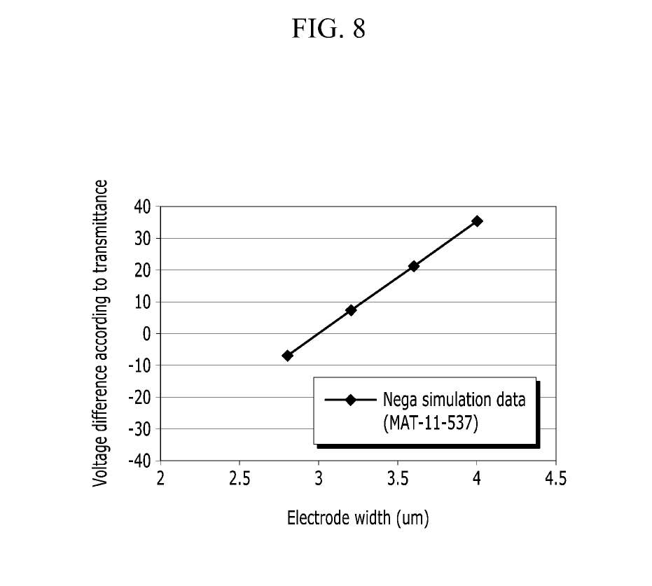

Hereinafter, an optimal electrode width which may reduce the difference in luminance under the above condition will be described with reference to FIG. 8 and the following Table 1.

FIG. 8 is a graph measuring a difference in transmittance according to voltages of the positive frame and the negative frame while the width of the slit electrode portion is changed under the same condition as FIG. 6A.

TABLE 1

| Width of slit | Voltage difference according to |
|---|---|
| electrode portion (μm) | transmittance (millivolts, mV) |
| 2.8 | −7 |
| 3.2 | 7 |
| 3.6 | 21 |
| 4.0 | 35 |

As shown in FIG. 8 and Table 1, when a distance between the slit electrode portions is about 8 μm, a cell gap is about 3.0 μm, and a thickness of an insulating layer is about 3,000 Å, transmittance according to a voltage in the positive frame and the negative frame in an exemplary embodiment, where the width of the slit electrode portion is about 3.0 μm, is substantially the same as each other.

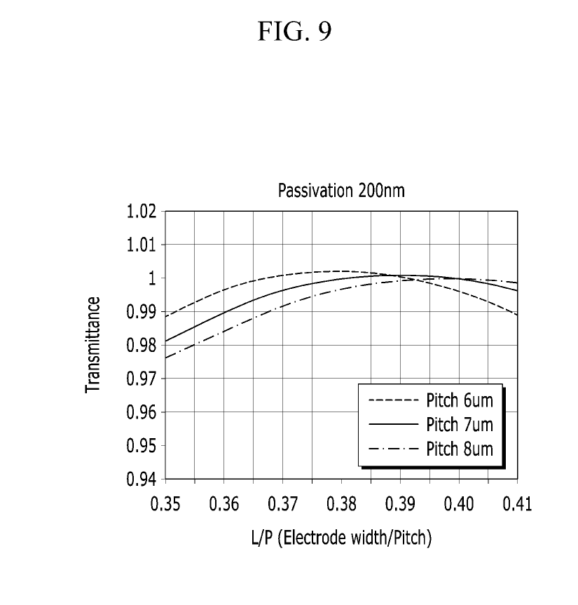

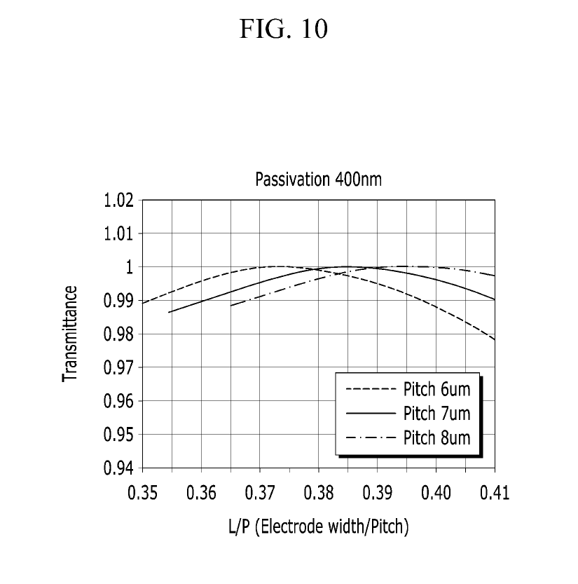

Next, a width of the slit electrode portion of an exemplary embodiment of the liquid crystal display will be described with reference to FIGS. 9 and 10.

FIG. 9 is a graph measuring luminance according to a width of the slit electrode portion over a distance between the slit electrode portions, when a thickness of the insulating layer is about 200 nanometers (nm). FIG. 10 is a graph measuring luminance according to a width of the slit electrode portion over a distance between the slit electrode portions, when a thickness of the insulating layer is about 400 nm.

Horizontal axes of graphs in FIGS. 9 and 10 represent a width of the slit electrode portion over a distance between the slit electrode portions, and vertical axes represent transmittance. The width of the slit electrode portion over the distance between the slit electrode portions, which has maximum luminance through the graphs in FIGS. 9 and 10, is shown in the following Table 2.

TABLE 2

| Distance between slit | Insulating layer thickness (μm) | | |
|---|---|---|---|
| electrode portions (μm) | 0.2 | 0.3 | 0.4 |
| 6 | 0.38 | 0.36 | 0.34 |
| 7 | 0.39 | 0.37 | 0.35 |
| 8 | 0.40 | 0.38 | 0.36 |

As a result, a relationship between the width of the slit electrode portion over the distance between the slit electrode portions and the thickness of the insulating layer in an exemplary embodiment of a liquid crystal display, in which a flicker is substantially minimized and luminance is substantially improved, may satisfy the following equation: L/P=0.01x−0.2y+0.36.

In the equation above, L denotes a width of the slit electrode portion, P denotes a distance between the slit electrode portions, x denotes a value of the distance between the slit electrode portions in micrometers, and y denotes a value of the thickness of the insulating layer in micrometers.

In such an embodiment, in which a flicker is substantially minimized and luminance is substantially improved, an error range in an optimal range of the relationship between the width of the slit electrode portion over the distance between the slit electrode portions and the thickness of the insulating layer may be about ±5%, and thus, the relationship between the width of the slit electrode portion over the distance between the slit electrode portions and the thickness of the insulating layer may satisfy the following in equation: 0.01x−0.2y+0.31≦L/P≦0.01x−0.2y+0.41.

In the in equation above, L denotes a width of the slit electrode portion, P denotes a distance between the slit electrode portions, x denotes a value of the distance between the slit electrode portions in micrometers, and y denotes a value of the thickness of the insulating layer in micrometers.

As described above, in an exemplary embodiment of the liquid crystal display, according to the invention, slits are defined in the pixel electrode such that a cross stem and minute branches extending from the cross stem are provided, and the common electrode is patterned at a position which is symmetric to the stem of the pixel electrode, such that visibility and transmittance are substantially improved, a texture is substantially reduced, and a color removal phenomenon and a gray aggregation phenomenon are effectively prevented.

The invention should not be construed as being limited to the exemplary embodiments set forth herein. Rather, these exemplary embodiments are provided so that this disclosure will be thorough and complete and will fully convey the concept of the present invention to those skilled in the art.

For example, another exemplary embodiment of the invention may include a method of manufacturing a liquid crystal display, which includes providing a common electrode and a pixel electrode on a substrate; providing an insulating layer between the common electrode and the pixel electrode; and providing a plurality of slit electrodes by forming a plurality of cutouts in at least one of the common electrode and pixel electrode, where a width of a slit electrode of the slit electrodes, a distance between the slit electrodes and a thickness of the insulating layer satisfy the following in equation: 0.01x−0.2y+0.31≦L/P≦0.01x−0.2y+0.41, where L denotes the width of the slit electrode, P denotes the distance between the slit electrodes, x denotes a value of a distance between the slit electrodes in micrometers, and y denotes a value of the thickness of the insulating layer in micrometers.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A liquid crystal display, comprising:
a substrate; and
a common electrode disposed on the substrate;
a pixel electrode disposed on the substrate; and
an insulating layer disposed between the common electrode and the pixel electrode,
wherein
at least one of the common electrode and the pixel electrode includes a plurality of slit electrodes defined by a plurality of cutouts defined therein, and
a width of a slit electrode of the slit electrodes, a distance between the slit electrodes and a thickness of the insulating layer satisfy the following in equation:
0.01x−0.2y+0.31≦L/P≦0.01x−0.2y+0.41,
wherein
L denotes the width of the slit electrode,
P denotes the distance between the slit electrodes,
x denotes a value of the distance between the slit electrodes in micrometers, and
y denotes a value of the thickness of the insulating layer in micrometers.

2. The liquid crystal display of claim 1, further comprising:
a gate line disposed on the substrate;
a first passivation layer disposed on the gate line and the substrate;
a semiconductor layer disposed on the insulating layer;
a data line and a drain electrode disposed on the semiconductor layer; and
a second passivation layer disposed on the data line and the drain electrode,
wherein the common electrode and the pixel electrode are disposed on the second passivation layer.

3. The liquid crystal display of claim 1, wherein
the width of the slit electrode, the distance between the slit electrodes, and the thickness of the insulating layer satisfy the following equation:
L/P=0.01x−0.2y+0.36.

4. The liquid crystal display of claim 1, wherein
the pixel electrode and the common electrode comprise a transparent conductive layer.

5. The liquid crystal display of claim 2, wherein the data line comprises:
a first curved portion having a curved shape, and
a second curved portion curved to form a predetermined angle with the first curved portion.

6. The liquid crystal display of claim 5, further comprising:
a source electrode disposed on the semiconductor layer,
wherein the source electrode and the data line are disposed along a same line.

7. The liquid crystal display of claim 5, wherein
the drain electrode and the data line extend substantially parallel to each other.

8. The liquid crystal display of claim 5, wherein
the common electrode comprises a curved edge substantially parallel to the first curved portion and the second curved portion of the data line.

9. A manufacturing method of a liquid crystal display, the manufacturing method comprising:
providing a common electrode and a pixel electrode on a substrate;
providing an insulating layer between the common electrode and the pixel electrode; and
providing a plurality of slit electrodes by forming a plurality of cutouts in at least one of the common electrode and pixel electrode,
wherein
a width of the slit electrode of the slit electrodes, a distance between the slit electrodes and a thickness of the insulating layer satisfy the following in equation:
0.01x−0.2y+0.31≦L/P≦0.01x−0.2y+0.41,
wherein
L denotes the width of the slit electrode,
P denotes the distance between the slit electrodes,
x denotes a value of the distance between the slit electrodes in micrometers, and
y denotes a value of the thickness of the insulating layer in micrometers.

10. The manufacturing method of a liquid crystal display of claim 9, further comprising:
providing a gate line on the substrate;
providing a first passivation layer on the gate line and the substrate;
providing a semiconductor layer on the insulating layer;
providing a data line and a drain electrode on the semiconductor layer;
providing a second passivation layer on the data line and the drain electrode and below the common electrode and the pixel electrode on the second passivation layer.

11. The manufacturing method of a liquid crystal display of claim 9, wherein
the width of the slit electrode, the distance between the slit electrodes, and the thickness of the insulating layer satisfy the following equation:
L/P=0.01x−0.2y+0.36.

12. The manufacturing method of a liquid crystal display of claim 9, wherein
the pixel electrode and the common electrode comprise a transparent conductive layer.

13. The manufacturing method of a liquid crystal display of claim 10, wherein the data line comprises:
a first curved portion having a curved shape; and
a second curved portion curved to form a predetermined angle with the first curved portion.

14. The manufacturing method of a liquid crystal display of claim 13, further comprising:
providing a source electrode on the semiconductor layer,
wherein the source electrode and the data line are disposed along a same line.

15. The manufacturing method of a liquid crystal display of claim 13, wherein
the drain electrode and the data line extend substantially parallel to each other.

16. The manufacturing method of a liquid crystal display of claim 13, wherein
the common electrode comprises a curved edge substantially parallel to the first curved portion and the second curved portion of the data line.
